(19) United States
(12) Patent Application Publication
(10) Pub. No.: US 2025/0273470 A1
(43) Pub. Date: Aug. 28, 2025

(54) SYSTEMATIC DELAYERING OF CHIPS

(71) Applicant: International Business Machines Corporation, Armonk, NY (US)

(72) Inventors: Heather Nicole Polgrean, Lagrangeville, NY (US); Tiberiu Suto, Franklin, NY (US); Jeremy R. Fox, Georgetown, TX (US); Alexander Reznicek, Troy, NY (US); Bahman Hekmatshoartabari, White Plains, NY (US)

(21) Appl. No.: 18/588,081

(22) Filed: Feb. 27, 2024

(51) Int. Cl. H01L 21/304; H01L 21/67; H01L 21/687; H01L 21/8234

(52) U.S. Cl. CPC H01L 21/304; H01L 21/67092; H01L 21/68764; H10D 84/0158; H10D 84/038

(57) ABSTRACT

Embodiments are related to providing systematic delayering of chips, such as finFET chips, along with performing field failure and material investigation. Techniques include receiving information from a gyroscope unit, a vacuum stage being connected to a sample, the vacuum stage being configured to maintain a position of the sample to a polishing table. Techniques include adjusting the position of the sample based, at least in part, on the information received from the gyroscope unit.

### BACKGROUND

The present invention generally relates to computer systems, and more specifically, to computer-implemented methods, computer systems, and computer program products configured and arranged for providing systematic delayering of chips, such as finFET chips, and performing field failure and material investigation.

Integrated circuits or ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a fin type field effect transistor (FET), which is a type of nonplanar MOSFET formed a three-dimensional structure. FinFET devices include an arrangement of fins disposed on a substrate. The fins are formed from a semiconductor material. A gate stack is arranged over the fins and defines a channel region of the fins, while regions of the fins extending outwardly from the channel region define active source and drain regions of the device. Various state-of-the-art techniques can be used for forming the fin.

Another 3D device is the nanowire or nanosheet MOSFET, which is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure.

Semiconductor delayering can be performed for the detection of buried faults and failures. The continued trend of shrinking semiconductor features means that failure analysis is more challenging. Additionally, more advanced designs and complex 3D architectures result in an increasing number of wiring layers, more complex memory cells, and more sensitive gate structures. Because of this reduction in feature dimensions and increase in structure complexity, it would be useful to have device delayering techniques to detect electrical faults as well as other phenomena that contribute to device failure.

### SUMMARY

Embodiments of the present invention are directed to computer-implemented methods for providing systematic delayering of chips, along with investigation of field failures and materials. A non-limiting computer-implemented method includes receiving information from a gyroscope unit, a vacuum stage being connected to a sample, the vacuum stage being configured to maintain a position of the sample to a polishing table. The method includes adjusting the position of the sample based, at least in part, on the information received from the gyroscope unit.

According to one or more embodiments, a system includes a vacuum stage configured to hold a sample to maintain a position of the sample to a polishing table, and a gyroscope unit. The system includes a controller configured to receive information from the gyroscope unit, the controller being configured to adjust the position of the sample based, at least in part, on the information received from the gyroscope unit.

According to one or more embodiments, a system includes a vacuum stage configured to hold a sample to maintain a position of the sample to a polishing table. The system includes a first gyroscope unit connected to the vacuum stage and a second gyroscope unit connected to the polishing table. The system includes a controller configured to receive information from the first and second gyroscope units, the controller being configured to adjust the position of the sample based, at least in part, on the information received from the first and second gyroscope units.

According to one or more embodiments, a system is provided. The system includes a vacuum stage configured to hold a sample to maintain a position of the sample to a polishing table, a first piezoelectric motor connected to the vacuum stage, a second piezoelectric motor connected to the polishing table, and a gyroscope unit. The system includes a controller configured to receive information from the gyroscope unit, the controller being configured to cause the position of the sample to the polishing table to be adjusted by controlling at least one of the first piezoelectric motor or the second piezoelectric motor.

Other embodiments of the present invention implement features of the above-described methods in computer systems and computer program products.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a block diagram of an example computing environment for use in conjunction with one or more embodiments of the present invention;

FIG. 2 depicts a block diagram of the example system configured for providing systematic delayering of chips, along with investigation of field failures and materials, according to one or more embodiments of the present invention;

FIG. 3 depicts further details of the system according to one or more embodiments of the present invention; and

FIG. 4 depicts a flowchart of a computer-implemented method for systematic delayering of chips, along with investigation of field failures and materials, according to one or more embodiments of the present invention.

### DETAILED DESCRIPTION

One or more embodiments are directed to a computer-implemented method. The method includes receiving information from a gyroscope unit, a vacuum stage being connected to a sample, the vacuum stage being configured to maintain a position of the sample to a polishing table. The method includes adjusting the position of the sample based, at least in part, on the information received from the gyroscope unit. This provides the technical effects and technical advantages of having integrated gyroscopic stabilization for a polishing machine during the delayering process, which is beneficial for controlling precise movements and uniform material removal of a sample, such as a wafer/chip, at the nanometer scale.

In addition to one or more features described above or below, or as an alternative, further embodiments disclose where adjusting the position of the sample based, at least in part, on the information received from the gyroscope unit includes controlling a piezoelectric motor. This provides the technical effects and technical advantages of using piezoelectric motors for precise material removal based on information from the gyroscope.

In addition to one or more features described above or below, or as an alternative, further embodiments disclose where a piezoelectric motor is coupled to the vacuum stage. This provides the technical effects and technical advantages using piezoelectric motors for precise material removal and for precise control of the vacuum stage based on information from the gyroscope.

In addition to one or more features described above or below, or as an alternative, further embodiments disclose where the piezoelectric motor causes the position to be adjusted in response to the information received from the gyroscope unit. This provides the technical effects and technical advantages using piezoelectric motors for precise material removal and for precise control of the vacuum stage based on information from the gyroscope.

In addition to one or more features described above or below, or as an alternative, further embodiments disclose where a piezoelectric motor is coupled to a polishing mechanism of the polishing table. This provides the technical effects and technical advantages using piezoelectric motors for precise material removal and for precise control of the polishing mechanism of the polishing table based on information from the gyroscope.

In addition to one or more features described above or below, or as an alternative, further embodiments disclose where the piezoelectric motor causes the polishing mechanism to be adjusted in response to the information received from the gyroscope unit. This provides the technical effects and technical advantages by using piezoelectric motors for precise material removal and for precise control of the polishing mechanism of the polishing table based on information from the gyroscope.

In addition to one or more features described above or below, or as an alternative, further embodiments disclose where the gyroscope unit is coupled to the vacuum stage. This provides the technical effects and technical advantages by using the gyroscope for accurate orientation and angular velocity of the vacuum stage holding the wafer/chip.

In addition to one or more features described above or below, or as an alternative, further embodiments disclose where the gyroscope unit is coupled to the polishing table. This provides the technical effects and technical advantages by using the gyroscope for accurate orientation and angular velocity of the polishing table having the polishing mechanism.

In addition to one or more features described above or below, or as an alternative, further embodiments disclose where the position of the sample is further adjusted based, at least in part, on receiving sensor information from one or more sensors. This provides the technical effects and technical advantages of using sensors to detect distance, visual appearance, defect/failures, etc., during the delayering process.

In addition to one or more features described above or below, or as an alternative, further embodiments disclose where the position of the sample to the polishing table affects an amount of material removed from the sample. This provides the technical effects and technical advantages of controlling removal of material.

One or more embodiments are directed to a system. The system comprises a vacuum stage configured to hold a sample to maintain a position of the sample to a polishing table, and a gyroscope unit. The system comprises a controller configured to receive information from the gyroscope unit, the controller being configured to adjust the position of the sample based, at least in part, on the information received from the gyroscope unit. This provides the technical effects and technical advantages of having integrated gyroscopic stabilization for a polishing machine during the delayering process, which is beneficial for precise movements and uniform material removal of a sample, such as a wafer/chip, at the nanometer scale.

In addition to one or more features described above or below, or as an alternative, further embodiments disclose where adjusting the position of the sample based, at least in part, on the information received from the gyroscope unit comprises controlling a piezoelectric motor. This provides the technical effects and technical advantages using piezoelectric motors for precise material removal based on information from the gyroscope.

In addition to one or more features described above or below, or as an alternative, further embodiments disclose a piezoelectric motor is coupled to the vacuum stage. This provides the technical effects and technical advantages of using piezoelectric motors for precise material removal and for precise control of the vacuum stage based on information from the gyroscope.

In addition to one or more features described above or below, or as an alternative, further embodiments disclose where the piezoelectric motor causes the position to be adjusted in response to the information received from the gyroscope unit. This provides the technical effects and technical advantages using piezoelectric motors for precise material removal and for precise control of the vacuum stage based on information from the gyroscope.

In addition to one or more features described above or below, or as an alternative, further embodiments disclose where a piezoelectric motor is coupled to a polishing mechanism of the polishing table. This provides the technical effects and technical advantages using piezoelectric motors for precise material removal and for precise control of the polishing mechanism of the polishing table based on information from the gyroscope.

In addition to one or more features described above or below, or as an alternative, further embodiments disclose where the piezoelectric motor causes the polishing mechanism to be adjusted in response to the information received from the gyroscope unit. This provides the technical effects and technical advantages using piezoelectric motors for precise material removal and for precise control of the polishing mechanism of the polishing table based on information from the gyroscope.

In addition to one or more features described above or below, or as an alternative, further embodiments disclose where the gyroscope unit is coupled to the vacuum stage. This provides the technical effects and technical advantages by using the gyroscope for accurate orientation and angular velocity of the vacuum stage holding the wafer/chip.

In addition to one or more features described above or below, or as an alternative, further embodiments disclose where the gyroscope unit is coupled to the polishing table. This provides the technical effects and technical advantages by using the gyroscope for accurate orientation and angular velocity of the polishing table having the polishing mechanism.

In addition to one or more features described above or below, or as an alternative, further embodiments disclose where the position of the sample is further adjusted based, at least in part, on receiving sensor information from one or more sensors. This provides the technical effects and technical advantages of using sensors to detect distance, visual appearance, defect/failures, etc., during the delayering process.

In addition to one or more features described above or below, or as an alternative, further embodiments disclose where the position of the sample to the polishing table affects an amount of material removed from the sample. This provides the technical effects and technical advantages of controlling removal of material.

One or more embodiments are directed to a system. The system includes a vacuum stage configured to hold a sample to maintain a position of the sample to a polishing table. The system includes a first gyroscope unit connected to the vacuum stage and a second gyroscope unit connected to the polishing table. The system includes a controller configured to receive information from the first and second gyroscope units, the controller being configured to adjust the position of the sample based, at least in part, on the information received from the first and second gyroscope units. This provides the technical effects and technical advantages of having integrated gyroscopic stabilization for a polishing machine during the delayering process, which is beneficial for precise movements and uniform material removal of a sample, such as a wafer/chip, at the nanometer scale. The first and second gyroscopes are utilized to account for the position and movement of the vacuum stage as well as the position and movement of the polishing mechanism of the polishing table.

In addition to one or more features described above or below, or as an alternative, further embodiments disclose where adjusting the position of the sample based, at least in part, on the information received from the first and second gyroscope units comprises controlling a piezoelectric motor. This provides the technical effects and technical advantages using piezoelectric motors for precise positioning of the sample based on the first and second gyroscopes.

In addition to one or more features described above or below, or as an alternative, further embodiments disclose where a piezoelectric motor is coupled to the vacuum stage. This provides the technical effects and technical advantages by using piezoelectric motors for precise material removal by controlling movement of the vacuum stage.

In addition to one or more features described above or below, or as an alternative, further embodiments disclose where a piezoelectric motor is coupled to a polishing mechanism of the polishing table. This provides the technical effects and technical advantages by using piezoelectric motors for precise material removal by controlling movement of the polishing mechanism.

One or more embodiments are directed to a system. The system includes a vacuum stage configured to hold a sample to maintain a position of the sample to a polishing table. The systems include a first piezoelectric motor connected to the vacuum stage, a second piezoelectric motor connected to the polishing table, and a gyroscope unit. The system includes a controller configured to receive information from the gyroscope unit, the controller being configured to cause the position of the sample to the polishing table to be adjusted by controlling at least one of the first piezoelectric motor or the second piezoelectric motor. This provides the technical effects and technical advantages of having integrated gyroscopic stabilization for a polishing machine during the delayering process, which is beneficial for precise movements and uniform material removal of a sample, such as a wafer/chip, at the nanometer scale. The first and second piezoelectric motors are utilized to move of the vacuum stage and the polishing mechanism, respectively, in order to adjust/control the position of the sample to the polishing mechanism of the polishing table.

One or more embodiments of the invention describe computer-implemented methods, computer systems, and computer program products configured and arranged for providing systematic delayering of chips (such as finFET chips), along with field failure and material investigation. FinFET chips experience failures and defects that have to be investigated via mechanical delayering and optical examination. This investigation is performed manually and presents several challenges. For example, the layers in 7 nanometer (nm) finFET chips are extremely thin, and the skill level required to investigate unique failures necessitates the use of highly experienced professionals. As technology shrinks, these difficulties only continue to increase. Missing, damaging, or destroying a unique failure impacts the General Availability (GA). Manual delayering requires multiple iterative cycles of mechanical grinding, optical examination, and scanning electron microscopy (SEM) to approach the failure. In some cases, delayering processes can take days or weeks to reach the failure in the chip. Also, reproducibility is a constant challenge due to the manual nature of the investigation. There are no standardized practices to increase efficiency and turnaround time of jobs in queue, and this can impact time sensitive investigations. The presence of a few trained professionals means that at times jobs will have no one to work on them, and tools like the focused ion beam (FIB) can cost millions of dollars and require trained engineers.

One or more embodiments provide an integration of delayering with gyroscopic stabilization to delayer materials of the sample (e.g., wafer/chip) in order to detect and determine the failure or defect. In the system, piezoelectric motors work in conjunction with the gyroscopic stabilization of the vacuum stage holding the sample (e.g., wafer/chip) and/or with gyroscopic stabilization of the polishing mechanism removing material from the wafer/chip. While the gyroscopes maintain the overall stability and orientation of the vacuum stage holding the sample, the piezoelectric motors can make fine adjustments in position or pressure of the sample against the polishing mechanism in response to the feedback from the gyroscopes. Machine learning models can be utilized to detect and determine faults and defects in the sample during the delayering process. Feedback loops are provided for continuous (e.g., real-time) improvement for the collected data. These feedback loops can help continuously improve the polishing process, by adapting to new types of chips and by enhancing defect detection algorithms of the machine learning models.

Technical effects and technical solutions provide a novel apparatus and method that enable the automatic delayering of (finFET) chips and similar samples in a manner that improves turnaround time, reproducibility, and ease of use (user experience). A highly trained subject matter expert is not required. The device is configured to exponentially reduce the time needed to find and isolate failures. Found defects and failures are relayed back to the design teams and the foundries in order to improve reliability and improve yield of chips. Having a faster, more reliable method of identifying defects and failures enables more rapid innovation and process improvement for chips used in processing systems. According to one or more embodiments, the device removes barriers to entry that exist for manual techniques and enables a wider range of users, who do not have to be limited to a few highly trained professionals. In one or more embodiments, the automated delayering processes can take only a few days (or shorter) as opposed to weeks to reach the failure. The device improves reproducibility and standardization of failure/defect identification, removes the iterative nature of the work, and reduces cost (e.g., time and the production of defective chips).

One or more embodiments described herein can utilize machine learning techniques to perform tasks, such as classifying a feature of interest. More specifically, one or more embodiments described herein can incorporate and utilize rule-based decision making and artificial intelligence (AI) reasoning to accomplish the various operations described herein, namely classifying a feature of interest. The phrase “machine learning” broadly describes a function of electronic systems that learn from data. A machine learning system, engine, or module can include a trainable machine learning algorithm that can be trained, such as in an external cloud environment, to learn functional relationships between inputs and outputs, and the resulting model (sometimes referred to as a “trained neural network,” “trained model,” “a trained classifier,” and/or “trained machine learning model”) can be used for classifying a feature of interest, for example. In one or more embodiments, machine learning functionality can be implemented using an Artificial Neural Network (ANN) having the capability to be trained to perform a function. In machine learning and cognitive science, ANNs are a family of statistical learning models inspired by the biological neural networks of animals, and in particular the brain. ANNs can be used to estimate or approximate systems and functions that depend on a large number of inputs. Convolutional Neural Networks (CNN) are a class of deep, feed-forward ANNs that are particularly useful at tasks such as, but not limited to analyzing visual imagery and natural language processing (NLP). Recurrent Neural Networks (RNN) are another class of deep, feed-forward ANNs and are particularly useful at tasks such as, but not limited to, unsegmented connected handwriting recognition and speech recognition. Other types of neural networks are also known and can be used in accordance with one or more embodiments described herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as delayering software code 150. In addition to delayering software code 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and delayering software code 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

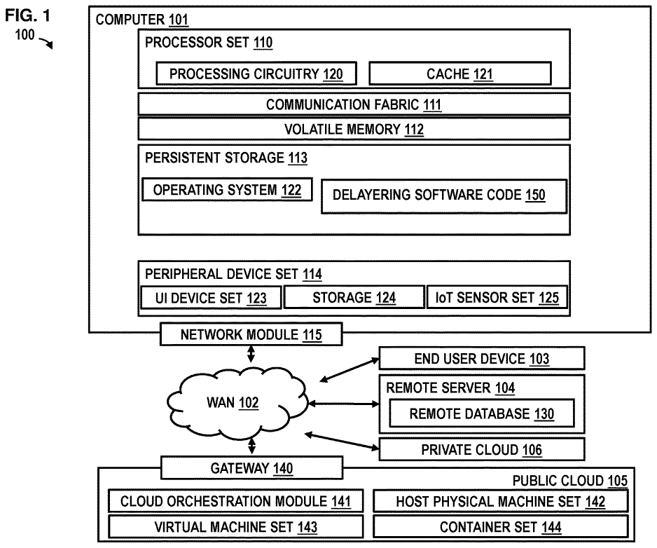

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in delayering software code 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in delayering software code 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

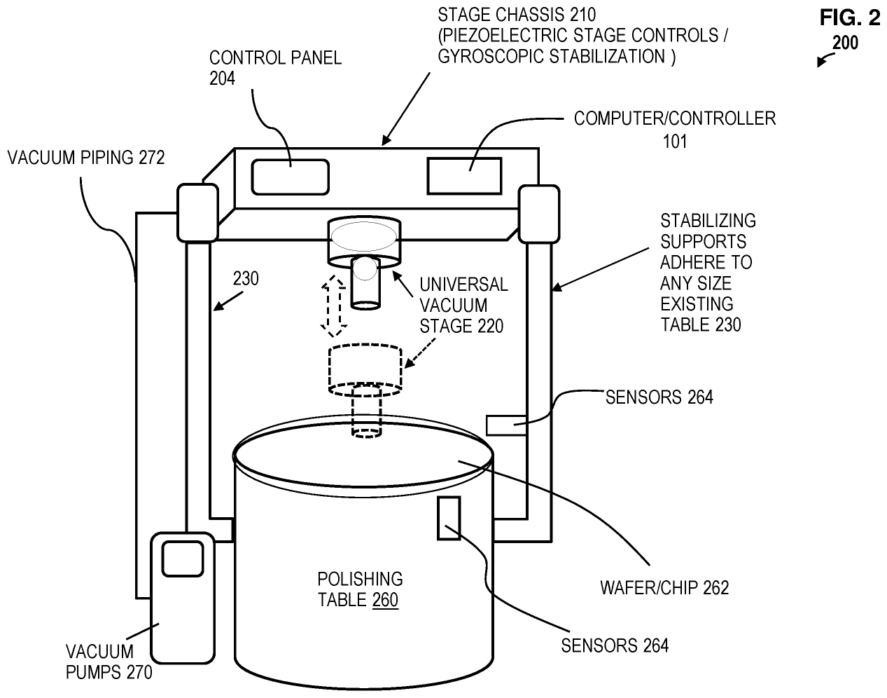

FIG. 2 depicts a block diagram of a system 200 as an example setup for providing systematic delayering of chips, along with investigation of field failures and materials according to one or more embodiments. The system 200 can be part of and/or coupled to the computing environment 100. In FIG. 2 and other figures herein, some details of the computing environment 100 may be omitted so as not to obscure the figure while new details are presented. Any features of the computing environment 100 in FIG. 1 can be utilized in the system 200 and/or with the computer system 200, according to one or more embodiments. The computer 101 can include the delayering software code 150 configured for systematic delayering of chips, along with investigation of field failures and materials. The delayering software code 150 can include, call, and/or be integrated with numerous pieces of software including application programming interfaces (APIs), algorithms, etc.

The system 200 can include a polishing table 260. The system 200 includes a small vacuum system, which can include vacuum pumps 270, vacuum piping 272, and a universal vacuum stage 220 for suctioning the wafer/chip 262. The universal vacuum stage 220 holds samples (e.g., wafer/chip 262) onto a (gyroscopically stabilized) stage chassis 210 that enables the system 200 to uniformly remove material from the wafer/chip 262.

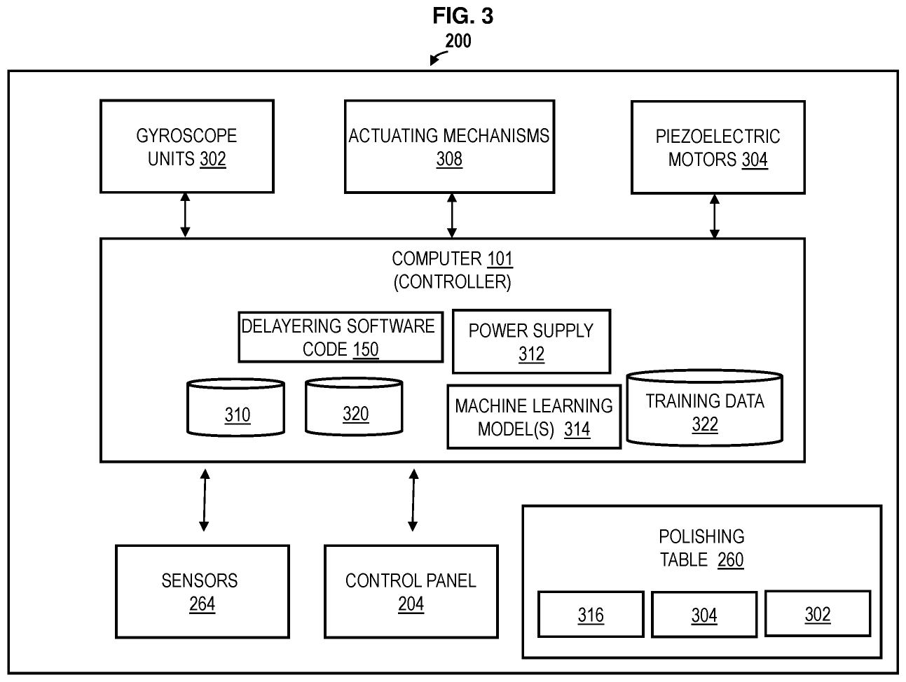

Gyroscopically stabilized piezoelectric motors (e.g., piezoelectric motors 304 depicted in FIG. 3) attached to the universal vacuum stage 220 keep the sample (e.g., wafer/chip 262) flush with the polishing table 260 to prevent differential material removal and sense the amount of material removed to the nanometer (nm) scale. This can remove 1, 2, 3, 4, 5, 10, 15, through 20 nanometers of material of the sample. The piezoelectric motors 304 receive input from a gyroscopic unit 302 (e.g., depicted in FIG. 3) having one or more gyroscopes to determine and provide positioning information, such that the piezoelectric motors 304 can make minor adjustments, for example, nanometer adjustments to the wafer/chip 262 in contact with the polishing surface of the polishing table 260. The gyroscopic unit 302 can include one or more gyroscopes, an inertial measurement unit (IMU), etc., to measure or determine the position of the wafer/chip 262 and provide feedback to the computer 101 (e.g., controller), which then controls the piezoelectric motors 304 to move wafer/chip 262 accordingly. The gyroscopic unit 302 can also include the logic circuits and connections to provide the positional information. Moreover, it should be appreciated that the gyroscope ensures that the universal vacuum stage 220 remains stable and correctly oriented, while the piezoelectric elements in the piezoelectric motors 304 provide precise, minute adjustments to maintain the ideal polishing conditions for the wafer/chip 262. This synergy between the two allows for a highly controlled and accurate polishing process.

The system 200 can include a database 310 (e.g., depicted in FIG. 3) that holds the uploaded schematics for the chip design of the wafer/chip 262 being delayered. The system 200 can include a database 320 equipped with preset modes that can expedite sample setup, improve result confidence, maintain active records on where fails/defects occur, and improve the settings used to isolate the fails/defects.

In one or more embodiments, the system 200 can include one or more sensors 264 providing feedback on the delayering and movement of the wafer/chip 262. The sensors 264 can include image sensors (such as cameras), infrared (IR) sensors (or thermal sensors), temperature sensors, distance sensors (including radars, lasers, etc.), ultrasound sensors, video sensors, pressure sensors, etc. The feedback from the sensors 264 is utilized by the computer 101 (e.g., controller) to control the piezoelectric motors 304. Moreover, one or more of the sensors 264 could be part of the IoT sensor set 125. The computer 101 may include and/or be integrated with controllers for operating and interfacing with the sensors 264. The sensors 264 and respective controllers can collect data about the polishing process, such as pressure applied, amount of material removed, and detection of defects.

In one or more embodiments, the system 200 may be a tabletop device that rests atop a preexisting polishing wheel. In one or more embodiments, stabilizing supports 230 can be attached to the polishing table 260 (or any existing polishing table). Fasteners, brackets, etc., can be utilized to attach the stage chassis 210 to the polishing table 260.

FIG. 3 depicts a block diagram having further details of the system 200 according to one or more embodiments. In the gyroscope unit 302, the gyroscope is a device that uses the principles of angular momentum to maintain orientation. In the system 200, the gyroscope's role is to ensure stability of the wafer/chip 262 attached to the universal vacuum stage 220. The gyroscope can detect and correct any tilts or shifts in orientation of the of the wafer/chip 262 attached to the universal vacuum stage 220. According to one or more embodiments, this is beneficial in a precision task like polishing the wafer/chip 262, where even slight deviations can lead to errors.

The gyroscope can be a spinning wheel or disk in which the axis of rotation is free to assume any orientation. When rotating, the orientation of this axis is unaffected by tilting or rotation of the mounting, according to the conservation of angular momentum. The gyroscopic effect is the tendency of a rotating object to maintain its orientation. This effect is used to stabilize objects, as any force trying to change the orientation of the rotating object is countered by the gyroscope. In one or more embodiments, the gyroscope of the gyroscope unit 302 is mounted in and/or near the universal vacuum stage 220 in order to account for issues impacting the chip/polishing surface. Additionally, in one or more embodiments, the gyroscope of the gyroscope unit 302 is mounted in and/or near a polishing mechanism 316 of the polishing table 260 in order to account for issues impacting the chip/polishing surface. Using the output from the gyroscope of the gyroscope unit 302, the computer 101 (e.g., controller) is configured to control or eliminate the rotational effects on the wafer/chip 262 in order to prevent uneven polishing of the polishing mechanism 316 against the wafer/chip 262 and potential destruction of areas of interest on the wafer/chip 262.

The piezoelectric motors 304 include piezoelectric materials that generate an electric charge when mechanically stressed, and conversely, mechanically deform when an electric field is applied to them. In the system 200, these properties are utilized for fine control of the polishing process by controlling the precise movements (e.g., in nanometers) of the wafer/chip 262. By the computer 101 (e.g., controller) applying varying electrical voltages via a power supply 312, the piezoelectric materials can make precise, controlled movements or adjustments.

By the piezoelectric effect, piezoelectric materials deform when an electric voltage is applied to them. This property is reversible such that piezoelectric materials also generate an electric charge when mechanically stressed. Piezoelectric motors use this effect to create motion. Piezoelectric motors are known for their ability to produce very fine, precise movements. In accordance with embodiments, the computer 101 (e.g., controller) is configured to utilize this high precision in movement to control the universal vacuum stage 220 holding the wafer/chip 262 such that the wafer/chip 262 is positioned to and maintained in the desired contact with the polishing mechanism of the polishing table 260, by controlling the piezoelectric motors 304 that have the ability to hold the position with power off and to achieve very small incremental movements. Additionally, the computer 101 (e.g., controller) is configured to utilize this high precision in movement to control the polishing mechanism 316 pressed against the wafer/chip 262 such that the wafer/chip 262 is positioned to and maintained in the desired contact with the polishing mechanism 316, by controlling the piezoelectric motors 304 that have the ability to hold the position with power off and to achieve very small incremental movements.

The delayering software code 150 may include, call, and/or be integrated with one or more data processing and control algorithms. The algorithms process the data from the gyroscopes and command the actuating mechanisms 308 and the piezoelectric motors 304 accordingly. The algorithms perform calculations to determine the exact amount and direction of adjustment needed.

With regard to temperature compensation, piezoelectric materials are sensitive to temperature changes, which can affect their performance. One or more of the sensors 264 are configured to detect temperature, humidity, etc. The delayering software code 150 can include, call, and/or be integrated with temperature compensation controls or algorithms that ensure consistent operation under varying environmental conditions. Based on changes in temperature below and/or above predetermined thresholds, the delayering software code 150 can cause the power supply 312 to reduce and/or increase the voltage supplied to the piezoelectric materials of the piezoelectric motors 304 when making adjustments to the position of the sample (e.g., wafer/chip 262). Piezoelectric motors generally have fewer moving parts than conventional motors, which can reduce wear and tear. However, considering the precision required for one or more embodiments, regular calibration and maintenance of the system 200 is to be performed to ensure long-term accuracy and reliability.

The position of the wafer/chip 262 relates to the x-axis, y-axis, and z-axis. The position further includes six degrees of freedom (6 DOF) for the wafer/chip 262. Six degrees of freedom (6DOF), or sometimes six degrees of movement, refers to the six mechanical degrees of freedom of movement of a rigid body in three-dimensional space. Specifically, the body is free to change position as forward/backward (surge), up/down (heave), left/right (sway) translation in three perpendicular axes, combined with changes in orientation through rotation about three perpendicular axes, often termed yaw (normal axis), pitch (transverse axis), and roll (longitudinal axis).

Further, regarding the universal vacuum stage, the universal vacuum stage 220 is where the sample (e.g., wafer/chip 262) is held during the polishing process. By using the universal vacuum stage 220, the vacuum ensures that the workpiece is securely fixed in place without any physical clamps that might interfere with the polishing surface of the polishing table 260.

The system 200 provides integration of the gyroscope, piezoelectric motors, and vacuum stage control. The control panel 204 can provide a graphical user interface (GUI) for operating the system 200. The control panel 204 may be a touch screen, can have tactile inputs (e.g., knobs, buttons, levers, etc.), and is utilized to start/stop the delayering process for the attached wafer/chip 262.

For stabilization and positioning, the gyroscope of the gyroscope unit 302 provides real-time feedback on the orientation and movement of the universal vacuum stage 220. In one or more embodiments, the gyroscope unit 302 may be attached to and/or in the universal vacuum stage 220 as noted herein. For integration with the universal vacuum stage 220, the gyroscope can be integrated within the vacuum stage that holds the chip being polished by the polishing mechanism 316 of the polishing table 260. This integration ensures that any unintended movements or tilts of the universal vacuum stage 220 are quickly detected and corrected by the computer 101 (e.g., controller). For sensing orientation changes, the gyroscope continuously monitors the orientation of the universal vacuum stage 220. If there is any deviation from the desired orientation (e.g., due to external disturbances or vibrations), the gyroscope unit 302 detects this change. If any unintended movements and/or tilts are detected (e.g., due to vibrations or other external factors) by the gyroscope unit 302, this information is fed back to the computer 101 (e.g., controller, control system, etc.). Additionally, in one or more embodiments, a gyroscope unit 302 may be attached to and/or in the stage chassis 210. To adjust for environmental factors, the system 200 can be calibrated to account for environmental factors such as temperature changes, which could affect the sensitivity and performance of the gyroscopes of the gyroscope units 302.

The user interface displayed on the control panel 204 and/or any other display screen can provide a real-time status display to the operator. The real-time status display can include a dashboard that displays real-time information about the polishing process, such as current pressure, motion, temperature, and polishing duration. The delayering software code 150 is configured to output on the control panel 204, through speakers, etc., to the operator system alerts and notifications, especially for anomalies detected or any adjustments made by the machine learning algorithms.

The control panel 204 can provide many options to the user. In one or more embodiments, the control panel 204 can provide manual control options for the system 200. The manual control options provide manual controls for starting, stopping, and pausing the polishing process, as well as adjusting parameters like pressure and speed.

In one or more embodiments, the control panel 204 can provide automatic and preset configurations in the parameters database 320 for the operation of the system 200. The automatic and preset configurations allow users to select from preset configurations for different types of polishing jobs and different types of chips, and/or to create and save their own custom configurations. Particularly, using the control panel 204 and/or any display screen, the delayering software code 150 can provide programmable control for automated polishing from the parameters database 320 having preset modes. In accordance with one or more embodiments, preset parameters/configurations in the parameters database 320 are utilized by the delayering software code 150 to program/operate the piezoelectric motors 304 to execute specific polishing patterns, pressures, and durations, depending on the requirements of the specific chip being polished.

The piezoelectric motors are tailored to the specific requirements of chip polishing. This includes parameters for the range of motion, force, speed, and precision. The delayering software code 150 can have safety and error handling procedures for such a precision device. The safety and error handling procedures include safeguards against over-voltage and mechanical overextension, as well as protocols for handling unexpected situations or malfunctions.

The system 200 can have cloud-based data management that may utilize a cloud-based system for storing and managing chip schematics and polishing data. The cloud-based system can include one or more computer systems, like computer 101, in the private cloud 106 and/or public cloud 105. In one or more embodiments, various databases such as the databases 310 and 320 may be stored in the computer systems of the cloud-based system. The cloud-based system can receive input from the system 200 (e.g., machine) and provide necessary information, like specific polishing patterns or parameters based on chip schematics. Real-time data synchronization is provided between the system 200 (e.g., machine) and the cloud-based system. This ensures that any changes in chip schematics and/or polishing requirements are immediately reflected in the operation of the system 200.

Encryption can be utilized for communication between the system 200 and the computer systems of the cloud-based system. The procedure could encrypt data both in transit (as it moves between the system 200 and the cloud-based system) and at rest (when stored in the cloud-based system), thereby protecting sensitive information. Various secure authentication protocols may be utilized. For example, secure authentication protocols can be utilized for accessing the sensors 264. This could include multi-factor authentication for users accessing the cloud-based data management system. Regular software updates and patches are performed to ensure that the software running on the sensors 264, the system 200, and the cloud-based system are updated and patched to protect against vulnerabilities.

Authorization and registration software can be utilized for providing access control and audit trails, which provide strict access controls to limit who can access the data. The authorization and registration software can maintain the audit trails to monitor who accesses the data and when and to detect and prevent unauthorized access.

As discussed herein real-time synchronization can be utilized by having low latency network connections. The low latency network connections ensure the ability for real-time data transfer. This is useful for immediate updates and adjustments in the polishing process based on the latest chip schematics or detected defects. One or more embodiments may utilize edge computing for immediate processing. The edge computing can be used where data processing is done close to the source (i.e., the system 200 itself). This can reduce reliance on cloud connectivity for real-time decision-making and action. The system 200 can have and/or be connected to backup and recovery systems to prevent data loss and ensure business continuity in case of system failures.

Turning to an example scenario further detailing the feedback mechanism, the gyroscopes of the gyroscope units 302 are connected to the computer 101 as a feedback control system. When the gyroscope detects a change in orientation, the gyroscope unit 302 sends signals to the computer 101. Based on the signals received, the computer 101 can determine if a large correction/movement is needed and/or if a small correction/movement is needed. The small correction/movement is for corrections below a predetermined threshold such as fine, precision movements, which can be performed by controlling the piezoelectric motors 304. In response to the gyroscope's signals and when the computer 101 determines that large corrections/movements are needed, the computer 101 is configured to control the actuating mechanisms 308 (which can include motors or servos) to correct the orientation. For instance, if the gyroscope detects a tilt, motors/servos of the actuating mechanisms 308 attached to the universal vacuum stage 220 can be activated to counteract this tilt and bring the universal vacuum stage 220 back to its intended position, when large corrections/movements are needed. In some cases, both small and large corrections/movements may be needed in response to signals from the gyroscope unit 302. Accordingly, the computer 101 can control both the actuating mechanisms 308 for large correction and the piezoelectric motors 304 for small corrections.

It should be appreciated that the computer 101 controls the actuating mechanisms 308 and the piezoelectric motors 304 to make real-time adjustments based on the signals from the gyroscope unit 302, because beneficial gyroscopic stabilization provides speed and accuracy for these adjustments. The system 200 reacts almost instantaneously to maintain the precision required in metallurgical polishing performed by the polishing table 260. For redundancy and precision and as discussed herein, multiple gyroscope units 302 may be used for redundancy and increased precision. With more than one gyroscope, the system 200 can more accurately detect and correct even very small deviations from the desired orientation.

For polishing process control, the piezoelectric elements in the piezoelectric motors 304 can also be used to control the pressure and movement of the polishing mechanism 316 based on the data received from the gyroscope in the gyroscope unit 302. This ensures that the polishing is uniform and precise, even if there are slight movements in the system 200 or the environment.

To provide data integration and feedback loops, the computer 101 (e.g., controller) is part of a feedback loop where data from the gyroscope (about the stage's orientation and stability) and data from the piezoelectric motors 304 (about the adjustments made) are continuously monitored and integrated by the computer 101. This allows for real-time adjustments to be made by the computer 101 during the polishing process, ensuring high precision and consistency.

As further details for driving the polishing mechanism 316, piezoelectric motors 304 are not only attached to the universal vacuum stage 220, but the piezoelectric motors 304 can also be directly connected to the components that control the polishing action of the polishing mechanism 316. The polishing mechanism 316 may be implemented as a polishing head or any suitable device as understood by one of ordinary skill in the art. The piezoelectric motors 304 directly attached to the polishing mechanism 316 are responsible for the fine control of the polishing head's movement, ensuring precise abrasion of the material of the wafer/chip 262. As part of the feedback control system, the piezoelectric motors 304 attached to the polishing mechanism 316 are controlled by the computer 101 in response to receiving signals from the gyroscopes of the gyroscope units 302 and/or sensors 264 (e.g., optical sensors) to monitor the status of the polishing process. For ultra-precise adjustments, the ability of piezoelectric motors 304 to make extremely small adjustments makes them ideal for applications where the amount of material removed must be controlled with high precision. By applying voltage to the piezoelectric elements via the power supply 312, piezoelectric elements of the piezoelectric motors 304 can be made to expand or contract very slightly. This movement can be translated into linear or rotational motion to control the position of the polishing head and/or the position of the universal vacuum stage 220.

As noted herein, sensors 264 (e.g., cameras, etc.) are mounted on the system 200. The sensors 264 (e.g., mounted cameras) can provide additional data to the delayering software code 150 of the computer 101 on the progress of the polishing, allowing for further refinement of the piezoelectric motor adjustments. This could be particularly useful in determining when the polishing has reached the desired level, especially in cases where failure detection is to be found. In one or more embodiments, the delayering software code 150 can compare the images captured by the sensors 264 during the polishing process to one or more prestored images of failures/defects in the database 310 to determine when a failure/defect is found.

According to one or more embodiments, based on the images provided by the sensors 264, the delayering software code 150 can employ one or more machine learning models 314 to determine that a failure/defect is found. The machine learning model 314 is configured for defect analysis and detection. The machine learning model 314 includes one or more machine learning algorithms that analyze the collected data, for example, in a training data repository 322, of previous failures and defects to identify patterns in failures or defects, which then utilized to find and detect the defect in the wafer/chip 262 being polished. This can help in predicting and preventing future defects.

During the data collection and preprocessing for training data in the repository 322, the system 200 and/or another computer system can gather comprehensive data, which includes collecting a wide range of data from the polishing process, including pressure, motion, temperature, polishing duration, and the occurrence of any failures or defects for a wafer/chip being processed. When preprocessing the data for training data in repository 322, the data is cleaned and placed in a format to ensure it is suitable for machine learning analysis. This involves handling missing values, normalizing data, and possibly reducing dimensionality. Appropriate machine learning algorithms are selected for anomaly detection and false positive identification. Example options may include supervised learning methods (like support vector machines, neural networks, etc.) for known defect types, and unsupervised learning methods (like clustering or autoencoders) for unknown anomalies.

Training and validation are performed for the machine learning models 314. Algorithms of the machine learning models 314 can be trained using historical data (e.g., training data in the repository 322), ensuring there is a balanced dataset that includes examples of both normal operations and various types of defects or failures. The machine learning models 314 can be validated using a separate set of data to check their accuracy and ability to generalize.

The machine learning models 314 can be embedded into the system 200 and/or one or more computer systems of the private cloud 106 and public cloud 105. In one or more embodiments, the machine learning models 314 can be part of the computer 101 for real-time data analysis during the polishing process. In one or more embodiments, the machine learning models 314 can be integrated in one or more edge computers for speed, in order utilize edge computing solutions to process data on-site with minimal latency; this is useful for making immediate adjustments based on machine learning insights.

Based on feedback from the user, reinforcement learning is performed for the machine learning models 314 to handle false positives and anomalies. This can include continuous learning and adjustment to the machine learning models 314, where the machine learning models 314 implement a continuous learning mechanism in which the computer 101 regularly (or continuously) updates the machine learning models 314 based on new data, thereby improving their accuracy over time. This provides iterative improvement of the machine learning models 314, based on testing and real-world use, in order to iteratively improve the machine learning algorithms and their integration into the system 200.

In one or more embodiments, there can be thresholds and alerts via the delayering software code 150 by setting thresholds for anomaly detection and establishing a system of alerts for potential issues. This involves balancing sensitivity (catching all true issues) with specificity (avoiding false alarms) for the machine learning models 314.

The delayering software code 150 may include, be integrated with, and/or call automated decision protocols. The automated decision protocols are for automatic adjustments or shutdowns if the system 200 detects a potential failure or defect. These decisions are calibrated to avoid overreacting to minor issues. Further, the control panel 204 has manual overrides to ensure that there is a mechanism for manual intervention. This allows an operator with the ability to override automated decisions if they deem it necessary.

From the machine learning insights, the system 200 is configured to display the results of the machine learning analysis, such as identified defects or potential issues on the wafer/chip 262. The delayering software code 150 can offer suggestions for adjustments based on the machine learning insights, with options for the user to accept, modify, or reject these suggestions. The selection by the user can be provided as feedback to the machine learning models 314 as reinforcement learning, for example, in real-time.

The system 200 can provide a feature for users to access and review historical data on past polishing jobs, including outcomes, machine settings, and any identified issues. Because the system 200 can use specific schematics for different wafers/chips, the system 200 provides a user-friendly interface for uploading and managing these schematics.

In one or more embodiments, the system 200 provides a customizable user interface that allow users to customize the layout of the dashboard according to their preferences and needs. The control panel 204 provides accessibility features such as adjustable text size, high-contrast modes, and voice commands, if applicable. The system 200 provides a secure login process, possibly with multi-factor authentication, especially for accessing sensitive data or controls. The system 200 provides accessibility according to user roles and permissions, which define different user roles with appropriate permissions, ensuring that only authorized personnel can access certain features or data.

Various training and help resources may be provided. The system 200 can provide integrated help and tutorials that may include integrated help sections, tutorials, and guides within the user interface in order to help users understand how to operate the machine and interpret its data. The system 200 can include a feedback mechanism for users to report issues or suggest improvements to the interface.

In one or more embodiments, the user interface is designed to be fast and responsive, with minimal lag, especially for real-time data display and control functionalities of the system 200. The user interface can be provided to a mobile device (e.g., laptop, phone, tablet, etc.) with a mobile-compatible version or an application for remote monitoring and control. The mobile device (which could be an end user device (EUD 103)) may include any of the hardware or software of computer 101 discussed in FIG. 1 and communicate with the system 200 over a network such as, for example, WAN 102.

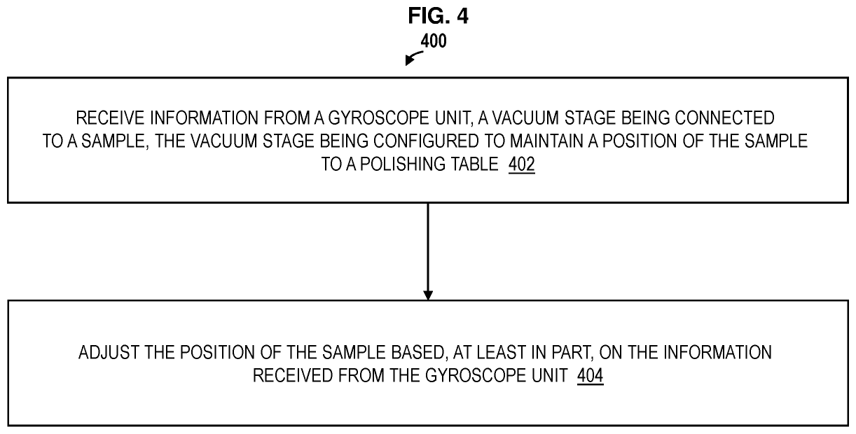

FIG. 4 depicts a flowchart of a computer-implemented method 400 for systematic delayering of chips, such as finFET chips, and performing field failure and material investigation according to one or more embodiments. Reference can be made to any of the figures discussed herein.

At block 402 of the computer-implemented method 400, the delayering software code 150 of the computer 101 is configured to receive information from a gyroscope unit 302, a vacuum stage (e.g., universal vacuum stage 220) being connected to a sample (e.g., wafer/chip 262), the vacuum stage (e.g., universal vacuum stage 220) being configured to maintain a position of the sample to a polishing table 260. At block 404 of the computer-implemented method 400, the delayering software code 150 of the computer 101 is configured to adjust the position of the sample (e.g., wafer/chip 262) based, at least in part, on the information received from the gyroscope unit 302.

In accordance with one or more embodiments, adjusting the position of the sample based, at least in part, on the information received from the gyroscope unit comprises controlling a piezoelectric motor 304. A piezoelectric motor 304 is coupled to the vacuum stage (e.g., universal vacuum stage 220). The piezoelectric motor 304 causes the position (of the wafer/chip 262) to be adjusted in response to the information received from the gyroscope unit 302. A piezoelectric motor 304 is coupled to a polishing mechanism 316 of the polishing table 260. The piezoelectric motor 304 causes the polishing mechanism 316 to be adjusted in response to the information received from the gyroscope unit 302. The gyroscope unit 302 is coupled to the vacuum stage (e.g., universal vacuum stage 220). The gyroscope unit 302 is coupled to the polishing table 260. The position of the sample (e.g., wafer/chips 262) is further adjusted based, at least in part, on receiving sensor information from one or more sensors 264. The position of the sample (e.g., wafer/chips 262) to the polishing table 260 affects an amount of material removed from the sample.

In one or more embodiments, the machine learning models 314 can include various engines/classifiers and/or can be implemented on a neural network. The features of the engines/classifiers can be implemented by configuring and arranging the computer system 101 to execute machine learning algorithms. In general, machine learning algorithms, in effect, extract features from received data in order to “classify” the received data. Examples of suitable classifiers include but are not limited to neural networks, support vector machines (SVMs), logistic regression, decision trees, hidden Markov Models (HMMs), etc. The end result of the classifier's operations, i.e., the “classification,” is to predict a class (or label) for the data. The machine learning algorithms apply machine learning techniques to the received data in order to, over time, create/train/update a unique “model.” The learning or training performed by the engines/classifiers can be supervised, unsupervised, or a hybrid that includes aspects of supervised and unsupervised learning. Supervised learning is when training data is already available and classified/labeled. Unsupervised learning is when training data is not classified/labeled so must be developed through iterations of the classifier. Unsupervised learning can utilize additional learning/training methods including, for example, clustering, anomaly detection, neural networks, deep learning, and the like.

In one or more embodiments, the engines/classifiers are implemented as neural networks (or artificial neural networks), which use a connection (synapse) between a pre-neuron and a post-neuron, thus representing the connection weight. Neuromorphic systems are interconnected elements that act as simulated “neurons” and exchange “messages” between each other. Similar to the so-called “plasticity” of synaptic neurotransmitter connections that carry messages between biological neurons, the connections in neuromorphic systems such as neural networks carry electronic messages between simulated neurons, which are provided with numeric weights that correspond to the strength or weakness of a given connection. The weights can be adjusted and tuned based on experience, making neuromorphic systems adaptive to inputs and capable of learning. After being weighted and transformed by a function (i.e., transfer function) determined by the network's designer, the activations of these input neurons are then passed to other downstream neurons, which are often referred to as “hidden” neurons. This process is repeated until an output neuron is activated. Thus, the activated output neuron determines (or “learns”) and provides an output or inference regarding the input.

Training datasets (e.g., training data in repository 322) can be utilized to train the machine learning algorithms. The training datasets can include historical data of past tickets and the corresponding options/suggestions/resolutions provided for the respective tickets. Labels of options/suggestions can be applied to respective tickets to train the machine learning algorithms, as part of supervised learning. For the preprocessing, the raw training datasets may be collected and sorted manually. The sorted dataset may be labeled (e.g., using the Amazon Web Services® (AWS®) labeling tool such as Amazon SageMaker® Ground Truth). The training dataset may be divided into training, testing, and validation datasets. Training and validation datasets are used for training and evaluation, while the testing dataset is used after training to test the machine learning model on an unseen dataset. The training dataset may be processed through different data augmentation techniques. Training takes the labeled datasets, base networks, loss functions, and hyperparameters, and once these are all created and compiled, the training of the neural network occurs to eventually result in the trained machine learning model (e.g., trained machine learning algorithms). Once the model is trained, the model (including the adjusted weights) is saved to a file for deployment and/or further testing on the test dataset.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method comprising:
receiving information from a gyroscope unit, a vacuum stage being connected to a sample, the vacuum stage being configured to maintain a position of the sample to a polishing table; and
adjusting the position of the sample based, at least in part, on the information received from the gyroscope unit.

2. The computer-implemented method of claim 1, wherein adjusting the position of the sample based, at least in part, on the information received from the gyroscope unit comprises controlling a piezoelectric motor.

3. The computer-implemented method of claim 1, wherein a piezoelectric motor is coupled to the vacuum stage.

4. The computer-implemented method of claim 3, wherein the piezoelectric motor causes the position to be adjusted in response to the information received from the gyroscope unit.

5. The computer-implemented method of claim 1, wherein a piezoelectric motor is coupled to a polishing mechanism of the polishing table.

6. The computer-implemented method of claim 5, wherein the piezoelectric motor causes the polishing mechanism to be adjusted in response to the information received from the gyroscope unit.

7. The computer-implemented method of claim 1, wherein the gyroscope unit is coupled to the vacuum stage.

8. The computer-implemented method of claim 1, wherein the gyroscope unit is coupled to the polishing table.

9. The computer-implemented method of claim 1, wherein the position of the sample is further adjusted based, at least in part, on receiving sensor information from one or more sensors.

10. The computer-implemented method of claim 1, wherein the position of the sample to the polishing table affects an amount of material removed from the sample.

11. A system comprising:
a vacuum stage configured to hold a sample to maintain a position of the sample to a polishing table;
a gyroscope unit; and
a controller configured to receive information from the gyroscope unit, the controller being configured to adjust the position of the sample based, at least in part, on the information received from the gyroscope unit.

12. The system of claim 11, wherein adjusting the position of the sample based, at least in part, on the information received from the gyroscope unit comprises controlling a piezoelectric motor.

13. The system of claim 11, wherein a piezoelectric motor is coupled to the vacuum stage.

14. The system of claim 13, wherein the piezoelectric motor causes the position to be adjusted in response to the information received from the gyroscope unit.

15. The system of claim 11, wherein a piezoelectric motor is coupled to a polishing mechanism of the polishing table.

16. The system of claim 15, wherein the piezoelectric motor causes the polishing mechanism to be adjusted in response to the information received from the gyroscope unit.

17. The system of claim 11, wherein the gyroscope unit is coupled to the vacuum stage.

18. The system of claim 11, wherein the gyroscope unit is coupled to the polishing table.

19. The system of claim 11, wherein the position of the sample is further adjusted based, at least in part, on receiving sensor information from one or more sensors.

20. The system of claim 11, wherein the position of the sample to the polishing table affects an amount of material removed from the sample.

21. A system comprising:
a vacuum stage configured to hold a sample to maintain a position of the sample to a polishing table;
a first gyroscope unit connected to the vacuum stage;
a second gyroscope unit connected to the polishing table;
a controller configured to receive information from the first and second gyroscope units, the controller being configured to adjust the position of the sample based, at least in part, on the information received from the first and second gyroscope units.

22. The system of claim 21, wherein adjusting the position of the sample based, at least in part, on the information received from the first and second gyroscope units comprises controlling a piezoelectric motor.

23. The system of claim 21, wherein a piezoelectric motor is coupled to the vacuum stage.

24. The system of claim 21, wherein a piezoelectric motor is coupled to a polishing mechanism of the polishing table.

25. A system comprising:
a vacuum stage configured to hold a sample to maintain a position of the sample to a polishing table;
a first piezoelectric motor connected to the vacuum stage;
a second piezoelectric motor connected to the polishing table;
a gyroscope unit; and
a controller configured to receive information from the gyroscope unit, the controller being configured to cause the position of the sample to the polishing table to be adjusted by controlling at least one of the first piezoelectric motor or the second piezoelectric motor.
